(19) United States
(12) Patent Application Publication
(10) Pub. No.: US 2020/0273970 A1
(43) Pub. Date: Aug. 27, 2020

(54) SEMICONDUCTOR DEVICE

(71) Applicant: Mitsubishi Electric Corporation, Chiyoda-ku (JP)

(72) Inventors: Satoshi OKUDA, Tokyo (JP); Akihiko FURUKAWA, Tokyo (JP); Akira KIYOI, Tokyo (JP)

(73) Assignee: Mitsubishi Electric Corporation, Chiyoda-ku (JP)

(21) Appl. No.: 16/494,411

(22) PCT Filed: Dec. 6, 2017
(86) PCT No.: PCT/JP2017/043796

§ 371 Date: Sep. 16, 2019

(30) Foreign Application Priority Data
May 10, 2017 (JP) 2017-093634

(51) Int. Cl. H01L 29/739

(52) U.S. Cl. CPC H01L 29/7397

(57) ABSTRACT

An object is to provide a technique that can suppress the surge voltage at turn-off without increasing the thickness of a semiconductor device such as an IGBT. A semiconductor device includes first to fourth semiconductor layers stacked in order of the first to fourth semiconductor layers, each having a first conductivity type, and also includes a base layer, an emitter layer, a gate electrode, a collector layer, and a collector electrode. The second semiconductor layer has the lowest impurity concentration of the first conductivity type among the first to fourth semiconductor layers, and the impurity concentration of the first conductivity type of the third semiconductor layer is higher than the impurity concentration of the first conductivity type of the fourth semiconductor layer.

### TECHNICAL FIELD

The present invention relates to a semiconductor device such as an Insulated Gate Bipolar Transistor (IGBT) and a manufacturing method thereof.

### BACKGROUND ART

Inverters used for various fields close to our lives such as industries, automobiles, electric railways, and the like are controlled by a power module or the like on which IGBTs are mounted. In order to achieve energy saving of such inverters, it is essential to reduce the power loss in the IGBTs that are responsible for the power control. Heretofore, to achieve both improvement of the saturation voltage of the IGBTs and reduction in the switching loss, thinning of IGBT chips has been promoted. Although the thickness of the chips is in a trade-off relationship with the reverse breakdown voltage, a Field Stop (FS) type IGBT is adopted as a structure for achieving both of them. In the FS type IGBT, an n type buffer layer having an impurity concentration higher than that of an n⁻ type drift layer is provided below the n⁻ type drift layer on the back surface of the chip. With such a configuration, a depletion layer is prevented from reaching a p⁺ type collector layer on the back surface of the chip when the IGBT is in the off state.

In recent years, thinning of the IGBT has progressed, and surge voltage and voltage oscillation at turn-off, which are caused by the thinning, have posed problems. These problems are caused by the depletion of carriers in the drift layer during the turn-off period to cause a sharp decrease in current.

In order to solve this problem, for example, as in the technique of Patent Document 1, it is proposed to make the ratio of the depletion layer extension to the voltage moderate by making the n type buffer layer relatively thick in the film thickness direction of the IGBT. Note that, in the following, a buffer layer that is wide in the film thickness direction is referred to as a “deep buffer layer”.

Patent Document 2 proposes a configuration in which a low impurity concentration layer is provided between an n type buffer layer and a p⁺ type collector layer. With such a configuration, holes are accumulated in the low impurity concentration layer in the conductive state, and the holes are supplied to the drift layer at turn-off, so that it is possible to suppress the rapid depletion of carriers.

### PRIOR ART DOCUMENTS

### Patent Documents

Patent Document 1: Japanese Patent Application Laid-Open No. 2015-179720

Patent Document 2: Japanese Patent Application Laid-Open No. 2002-305305

### SUMMARY

### Problems to be Solved by the Invention

In order to suppress the surge voltage at turn-off of the IGBT, it is effective to increase the impurity concentration in the deep buffer layer as in the technique of Patent Document 1. However, when the impurity amount in the deep buffer layer is increased, the withstand voltage of the IGBT is reduced, and therefore, there is a limit to the increase in the thickness of the deep buffer layer and the increase in impurity concentration.

As described above, in the configuration in which the thinning of the IGBT is excessively advanced, a sufficient surge voltage suppressing effect may not be obtained by merely providing the deep buffer layer. Furthermore, in the configuration in which the low impurity concentration layer is disposed between the n type buffer layer and the p⁺ type collector layer as in the technique of Patent Document 2, the depletion layer does not spread in the low impurity concentration layer, and thus no effect of retaining withstand voltage can be obtained. Therefore, there has been a problem in that the thickness of the IGBT is increased by the amount of the low impurity concentration layer, and the conduction loss is increased.

Therefore, the present invention has been made in view of the above problems, and it is an object of the present invention to provide a technique capable of suppressing a surge voltage at turn-off without increasing the thickness of a semiconductor device such as an IGBT.

### Means to Solve the Problems

A semiconductor device according to the present invention includes: first to fourth semiconductor layers stacked in order of the first to fourth semiconductor layers, each having a first conductivity type, a forward direction and a reverse direction of the stacking being respectively referred to as a first direction and a second direction; a base layer disposed on a surface side of the fourth semiconductor layer facing the first direction, the base layer having a second conductivity type; an emitter layer selectively disposed on a surface of the base layer facing the first direction, the emitter layer having the first conductivity type; a gate electrode capable of forming a channel in the base layer; a collector layer disposed on a side of the second direction of the first semiconductor layer, the collector layer having the second conductivity type; and a collector electrode disposed on a surface of the collector layer facing the second direction. An impurity concentration of the first conductivity type of one semiconductor layer which is one of the second semiconductor layer and the third semiconductor layer is lower than an impurity concentration of the first conductivity type of each of a semiconductor layer adjacent in the first direction to the one semiconductor layer and a semiconductor layer adjacent in the second direction to the one semiconductor layer. A hydrogen atom concentration in the one semiconductor layer is same as a hydrogen atom concentration in each of the semiconductor layer adjacent in the first direction to the one semiconductor layer and the semiconductor layer adjacent in the second direction to the one semiconductor layer.

### Effects of the Invention

According to the present invention, the impurity concentration of the first conductivity type of one semiconductor layer which is one of the second semiconductor layer and the third semiconductor layer is lower than the impurity concentration of the first conductivity type of each of the semiconductor layer adjacent in the first direction to the one semiconductor layer and the semiconductor layer adjacent in the second direction to the one semiconductor layer. With such a configuration, the surge voltage at turn-off can be suppressed without increasing the thickness of a semiconductor device such as an IGBT.

Objects, features, aspects, and advantages of the present invention will become more apparent from the following detailed description and the accompanying drawings.

### BRIEF DESCRIPTION OF DRAWINGS

FIG. 1 is a schematic cross-sectional view showing the configuration of a related semiconductor device.

FIG. 2 is a schematic cross-sectional view showing the configuration of a semiconductor device according to a first embodiment.

FIG. 3 is a diagram showing an impurity concentration profile of the semiconductor device according to the first embodiment.

FIG. 4 is a diagram showing an impurity concentration profile of a modification of the semiconductor device according to the first embodiment.

FIG. 5 is a schematic cross-sectional view for illustrating a manufacturing method according to a second embodiment.

FIG. 6 is a schematic cross-sectional view for illustrating the manufacturing method according to the second embodiment.

FIG. 7 is a schematic cross-sectional view for illustrating the manufacturing method according to the second embodiment.

FIG. 8 is a schematic cross-sectional view for illustrating the manufacturing method according to the second embodiment.

FIG. 9 is a schematic cross-sectional view for illustrating the manufacturing method according to the second embodiment.

FIG. 10 is a schematic cross-sectional view for illustrating a manufacturing method according to a third embodiment.

FIG. 11 is a schematic cross-sectional view for illustrating the manufacturing method according to the third embodiment.

FIG. 12 is a schematic cross-sectional view for illustrating the manufacturing method according to the third embodiment.

FIG. 13 is a schematic cross-sectional view for illustrating the manufacturing method according to the third embodiment.

FIG. 14 is a schematic cross-sectional view for illustrating the manufacturing method according to the third embodiment.

FIG. 15 is a diagram showing an impurity concentration profile of a semiconductor device according to a fourth embodiment.

FIG. 16 is a cross-sectional view schematically showing the configuration of a semiconductor device according to a fifth embodiment.

FIG. 17 is a diagram showing an impurity concentration profile of the semiconductor device according to the fifth embodiment.

FIG. 18 is a schematic cross-sectional view for illustrating a manufacturing method according to the fifth embodiment.

FIG. 19 is a schematic cross-sectional view for illustrating the manufacturing method according to a modification of the fifth embodiment.

FIG. 20 is a schematic cross-sectional view showing the configuration of a semiconductor device according to a sixth embodiment.

FIG. 21 is a diagram showing an impurity concentration profile of the semiconductor device according to the sixth embodiment.

### DESCRIPTION OF EMBODIMENTS

In the following description, n and p indicate conductivity types of a semiconductor. Furthermore, n⁻⁻ indicates an impurity concentration lower than n⁻, n⁻ indicates an impurity concentration lower than n, and n⁺ indicates an impurity concentration higher than n. Similarly, p⁻ indicates an impurity concentration is lower than p, and p⁺ indicates an impurity concentration higher than p.

In the following description, a first direction that is a forward direction of stacking of first to fourth semiconductor layers to be described later is an upward direction, and a second direction that is a reverse direction of the forward direction is a downward direction. The surface facing upward is described as an upper surface, and the surface facing downward is described as a lower surface. In addition, in the following description, it is assumed that the first conductivity type is n, n⁻, n⁻⁻, n⁺ and the second conductivity type is p, p⁻, p⁺, which may be reversed to each other.

<Related Semiconductor Device>

Before the description on semiconductor devices according to embodiments of the present invention, a semiconductor device related to these (hereinafter referred to as “related semiconductor device”) will be described.

FIG. 1 is a schematic cross-sectional view showing the configuration of a related semiconductor device. In the example of FIG. 1, the related semiconductor device is an FS type IGBT. A semiconductor structure 200 is prepared, for example, by performing a Floating Zone (FZ) method or a Magnetic field applied CZ (MCZ) method on a substrate containing n⁻ type silicon lightly doped with phosphorus.

The related semiconductor device illustrated in FIG. 1 includes a trench gate electrode 1, an emitter electrode 4, an n⁺ type emitter layer 5, a p type base layer 6, an n type carrier accumulation layer 7, an interlayer insulating film 8, a p⁺ type collector layer 9, a collector electrode 10, an n⁻ type drift layer 11, and an n⁺ type buffer layer 12.

The p type base layer 6 is provided on the upper surface side of the n⁻ type drift layer 11, and the n⁺ type emitter layer 5 is selectively provided on the upper surface of the p type base layer 6. The trench gate electrode 1 illustrated in FIG. 1 includes a gate insulating film 2 provided along an inner wall of a trench extending from the upper surface of the n⁺ type emitter layer 5 to the n⁻ type drift layer 11 and a gate electrode 3 embedded to be surrounded by the gate insulating film 2. The gate electrode 3 can form a channel with which conduction can be established between the n⁺ type emitter layer 5 and the n⁻ type drift layer 11, upon receiving gate voltage.

The related semiconductor device illustrated in FIG. 1 includes the n type carrier accumulation layer 7 between the p type base layer 6 and the n⁻ type drift layer 11.

The interlayer insulating film 8 is provided on the trench gate electrode 1 and on part of the n⁺ type emitter layer 5. The emitter electrode 4 is provided on the remaining portion of the n⁺ type emitter layer 5, on the p type base layer 6, and on the interlayer insulating film 8.

The lower surface of the n⁻ type drift layer 11 is provided with the n⁺ type buffer layer 12, the p⁺ type collector layer 9, and the collector electrode 10 in this order from the upper side. The n⁺ type buffer layer 12 is provided to prevent a reach-through, which is a phenomenon in which a depletion layer, extending from a pn junction surface of the p type base layer 6 into the n− type drift layer 11, reaches the p⁺ type collector layer 9 at turn-off.

To reduce conduction loss, the thinning of the n⁻ type drift layer 11 has been conventionally advanced. This thinning enables the speeding-up of turn-off, but the depletion layer spread in the n⁻ type drift layer 11 collides with the n⁺ type buffer layer 12. Therefore, electron emission from the n⁻ type drift layer 11 is suppressed, and hole supply from the p⁺ type collector layer 9 is suppressed. As a result, carriers in the n− type drift layer 11 are rapidly depleted, and the collector current is rapidly reduced. Then, a large surge voltage generated due to the rapid change in the collector current may exceed the element withstand voltage or generate noise oscillating in the voltage waveform.

As a means for solving this, there is known a means for suppressing exhaustion of carriers in the n⁻ type drift layer 11 by providing a deep buffer layer as the n⁻ type drift layer 11 and gently extending the depletion layer at turn-off. This means can increase the effect of suppressing the surge voltage by increasing the impurity concentration in the deep buffer layer. However, there is a case where the surge voltage cannot be sufficiently suppressed because the element withstand voltage decreases when the impurity concentration is increased.

As a configuration for solving such a problem, a configuration can be considered in which a low impurity concentration layer is provided between the n⁺ type buffer layer 12 and the p⁺ type collector layer 9. With this configuration, since holes are accumulated in the low impurity concentration layer in the conductive state and the holes are supplied to the n⁻ type drift layer 11 at turn-off, it is possible to suppress the rapid depletion of carriers. However, since the depletion layer does not spread in the low impurity concentration layer, the effect of holding the withstand voltage cannot be obtained. Therefore, the thickness of the chip of the related semiconductor device is increased by the amount of the low impurity concentration layer, and the conduction loss is increased. In contrast, as described below, in semiconductor devices according to embodiments of the present invention, it is possible to suppress the surge voltage at turn-off without increasing the thickness of the semiconductor devices.

### First Embodiment

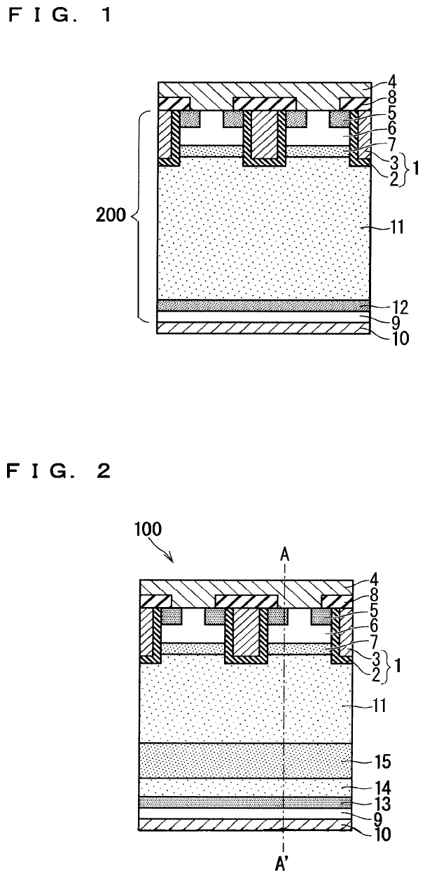

FIG. 2 is a schematic cross-sectional view showing the configuration of a semiconductor device 100 according to a first embodiment of the present invention. In the example of FIG. 2, the semiconductor device 100 is an FS type IGBT as with the related semiconductor device. The semiconductor device 100 has the same configuration as the configuration of the related semiconductor device of FIG. 1 except that the n⁺ type buffer layer 12, among the components thereof, is replaced with an n⁺ type first buffer layer 13, a n⁻ type back surface carrier accumulation layer 14, and a n type second buffer layer 15. Hereinafter, among the components described in the first embodiment, the same or similar components as or to the components described above are designated by the same reference numerals, and different components will be mainly described.

The semiconductor device 100 includes the n⁺ type first buffer layer 13 as a first semiconductor layer, the n− type back surface carrier accumulation layer 14 as a second semiconductor layer, the n type second buffer layer 15 as a third semiconductor layer, and the n⁻ type drift layer 11 as a fourth semiconductor layer. The n⁺ type first buffer layer 13, the n⁻ type back surface carrier accumulation layer 14, the n type second buffer layer 15, and the n⁻ type drift layer 11 are sequentially stacked from the bottom to the top. In the following description, the n⁺ type first buffer layer 13, the n⁻ type back surface carrier accumulation layer 14, the n type second buffer layer 15, and the n⁻ type drift layer 11 may be collectively referred to as “four semiconductor layers”.

Similar to the related semiconductor device, the semiconductor device 100 includes the trench gate electrode 1, the emitter electrode 4, the n⁺ type emitter layer 5, the p type base layer 6, the n type carrier accumulation layer 7, the interlayer insulating film 8, the p⁺ type collector layer 9, and the collector electrode 10.

The p type base layer 6 is disposed on the upper surface side of the n⁻ type drift layer 11, and the n⁺ type emitter layer 5 is selectively disposed on the upper surface of the p type base layer 6. The trench gate electrode 1 capable of forming a channel in p type base layer 6 is arranged to extend from the upper surface of the n⁺ type emitter layer 5 to the n⁻ type drift layer 11, and the gate electrode 3 is capable of forming a channel that enables conduction between the n⁺ type emitter layer 5 and the n⁻ type drift layer 11 upon receiving gate voltage. The p⁺ type collector layer 9 is disposed on the lower side of the n⁺ type first buffer layer 13, and the collector electrode 10 is disposed on the lower surface of the p⁺ type collector layer 9.

Although the semiconductor device 100 of FIG. 2 includes the n type carrier accumulation layer 7 between the p type base layer 6 and the n⁻ type drift layer 11, the n type carrier accumulation layer 7 is not essential.

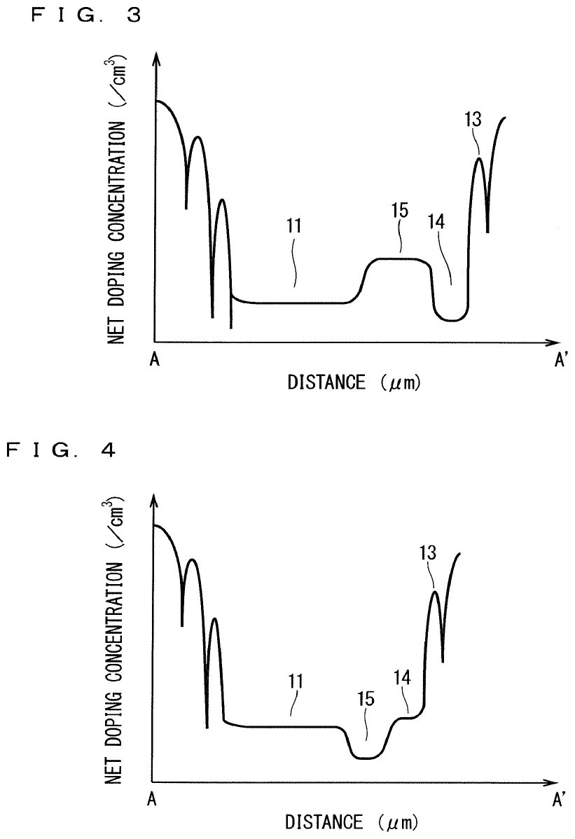

FIG. 3 is a diagram showing an impurity concentration profile along line A-A′ in FIG. 2, that is, a profile of net doping concentration.

The n type impurity concentration of one semiconductor layer which is one of the n⁻ type back surface carrier accumulation layer 14 and the n type second buffer layer 15 is lower than the n type impurity concentration of the each of the semiconductor layer adjacent in the upward direction to the one semiconductor layer and the semiconductor layer adjacent in the downward direction to the one semiconductor layer.

For example, the one semiconductor layer is the n⁻ type back surface carrier accumulation layer 14, and the n type impurity concentration of the n⁻ type back surface carrier accumulation layer 14 is lower than the n type impurity concentration of each of the n type second buffer layer 15 adjacent in the upward direction and the n⁺ type first buffer layer 13 adjacent in the downward direction. The n⁻ type back surface carrier accumulation layer 14 has the lowest n type impurity concentration among the four semiconductor layers described above. The n type impurity concentration of the n type second buffer layer 15 is higher than the n type impurity concentration of the n⁻ type drift layer 11.

Also, for example, the one semiconductor layer may be the n type second buffer layer 15. In this case, as shown in FIG. 4, the n type impurity concentration of the n type second buffer layer 15 is lower than the n type impurity concentration of each of the n⁻ type drift layer 11 adjacent in the upward direction and the n⁻ type back surface carrier accumulation layer 14 adjacent in the downward direction. In the following, the one semiconductor layer is described as the n⁻ type back surface carrier accumulation layer 14.

In the first embodiment, the profile of the net doping concentration of the four semiconductor layers is a step-like profile. The step-like profile is a profile having a portion where the concentration is substantially constant and a portion where a change in concentration is steep.

In addition, the hydrogen atom concentration in the n⁻ type back surface carrier accumulation layer 14 is the same as the hydrogen atom concentration in n in each of the n type second buffer layer 15 adjacent in the upward direction and the n⁺ type first buffer layer 13 adjacent in the downward direction. Here, sharing the same hydrogen atom concentration means that the hydrogen ion concentration difference between both regions is below a detection limit. For the detection limit, for example, a general definition of not more than three times the noise is adopted. Here, the standard deviation of the hydrogen concentration in the chip depth direction of a total of the four semiconductor layers and the standard deviation of the hydrogen concentration in the chip depth direction of each of the four semiconductor layers are not more than three times the standard deviation of the hydrogen ion concentration in the chip depth direction of the n⁻ type drift layer 11.

The lower limit of the thickness of the n⁻ type back surface carrier accumulation layer 14 is determined in a range in which the effect of carrier accumulation does not disappear, and is, for example, approximately 0.5 μm. The upper limit of the thickness of the n⁻ type back surface carrier accumulation layer 14 is, for example, 20 μm. However, the upper limit of the thickness of the n⁻ type back surface carrier accumulation layer 14 needs to be designed for the entire carrier profile of the n type layers so that the rated voltage of the semiconductor device 100 can be maintained. From the viewpoint of surge suppression of the turn-off voltage, it is preferable that the impurity surface density be high in order to stop the extension of the depletion layer. It is preferable that the thickness and the impurity concentration of the n⁻ type back surface carrier accumulation layer 14 be designed in a range that satisfies the impurity surface density of the n type layers designed in this way.

Furthermore, in order to prevent a reach-through, in which the depletion layer reaches the p⁺ type collector layer 9 at turn-off, it is more preferable that the impurity concentration of the n⁺ type first buffer layer 13 be high. On the other hand, if the concentration of the n⁺ type first buffer layer 13 is high, the injection efficiency of holes from the p⁺ type collector layer 9 in the conductive state is lowered. The decrease in the injection efficiency of holes from the p⁺ type collector layer 9 leads to a decrease in reliability of the semiconductor device 100 due to an increase in the on-voltage, an increase in the on-voltage variation due to the concentration variation of the p⁺ type collector layer 9, and an increase in the back surface field at turn-off. Therefore, the ratio between the impurity concentration peak of the p⁺ type collector layer 9 and the impurity concentration peak of the n⁺ type first buffer layer 13 needs to be appropriately determined. Specifically, the ratio is preferably 10 or more. By designing the device with such a concentration ratio, it is possible to achieve both suppression of reach-through and maintenance of hole injection efficiency. Furthermore, as described above, the concentration profile of the entire n type layers needs to be designed so as not to exceed the upper limit of the impurity surface density defined by the thickness of the n type layers and the withstand voltage.

Furthermore, the n type second buffer layer 15 has an effect of confining holes into the n⁻ type back surface carrier accumulation layer 14 and an effect of suppressing the spread of the depletion layer extending from the surface at turn-off. Therefore, the impurity concentration of the n type second buffer layer 15 is required to be sufficiently higher than the impurity concentration of the n⁻ type back surface carrier accumulation layer 14. Specifically, the concentration ratio between the impurity peak concentration of the n type second buffer layer 15 and the impurity peak concentration of the n⁻ type back surface carrier accumulation layer 14 is preferably 3 or more, and more preferably 10 or more. By designing such an impurity concentration profile, the spread of the depletion layer can be suppressed while suppressing the depletion of holes on the back surface.

### Gist of First Embodiment

With the configuration of the semiconductor device 100 according to the first embodiment, part of the holes injected from the p⁺ type collector layer 9 is accumulated in the n⁻ type back surface carrier accumulation layer 14 in the conductive state. At turn-off, the depletion layer from the upper pn junction surface, such as the pn junction surface of the p type base layer 6, extends in the n⁻ type drift layer 11. In this process, the amount of remaining carriers in the semiconductor device 100 according to the first embodiment is larger than that in the related semiconductor device due to the effect that part of the holes is retained by the n⁻ type back surface carrier accumulation layer 14, which can delay depletion of carriers in the n⁻ type drift layer 11. Thereby, it is possible to suppress a sharp decrease in collector current during the turn-off period, and it is possible to reduce the surge voltage generated with a rapid decrease in current.

In addition, the n type second buffer layer 15 provided on the n⁻ type back surface carrier accumulation layer 14 acts as a deep buffer layer structure that suppresses the extension of the depletion layer, so that the surge voltage can be further reduced. As described above, by providing the n⁻ type back surface carrier accumulation layer 14 and the n type second buffer layer 15, the surge voltage suppressing effect can be enhanced without increasing the thickness of the chip. As a result, it is possible to provide a power module capable of suppressing defects that have occurred when an overvoltage is applied to semiconductor devices such as IGBTs and also capable of reducing noise.

### Second Embodiment

Conventionally, several methods have been proposed as methods for forming a deep buffer layer structure. For example, a method is known that includes, after forming a shallow n type buffer layer by ion implantation of phosphorus, forming a buffer layer having a concentration gradient to a deep portion by ion implantation of selenium or sulfur, both of which have a diffusion coefficient larger than that of phosphorus. However, since selenium is not used in general semiconductor processes, a dedicated and expensive ion implantation apparatus is required, and there is a concern that other devices may be contaminated when a diffusion furnace or the like is used. Furthermore, in general, selenium and sulfur have a range of about 1 μm in ion implantation, and it is thus difficult to form a layered structure of the semiconductor device 100 according to the first embodiment, that is, a layered structure composed of a large number of layers including the n⁻ type back surface carrier accumulation layer 14 and having different concentrations.

There is also known a method of forming multilayer semiconductor layers by applying proton (H ⁺) irradiation in multiple steps while changing the acceleration energy and the dose amount. However, proton irradiation requires an accelerator such as a cyclotron, and there is a problem in that the installation place of the accelerator, that is, the place where the accelerator can provide irradiation is limited. In addition, since crystal defects occur in the semiconductor region through which protons pass, leakage current in the off state of the IGBT inevitably increases. In addition, the impurity concentration profile formed by proton irradiation has a Gaussian distribution. For this reason, when the areas of the foot of two Gaussian distributions, formed by proton irradiation in two steps, are used as low impurity concentration layers, it is necessary to separate the peaks of the two Gaussian distributions sufficiently such that the concentration of the low impurity concentration layers can be sufficiently lowered. However, this requires proton irradiation from the lower surface (back surface) to a deep position of the IGBT with a high acceleration voltage, which has the problem of further increased crystal defects.

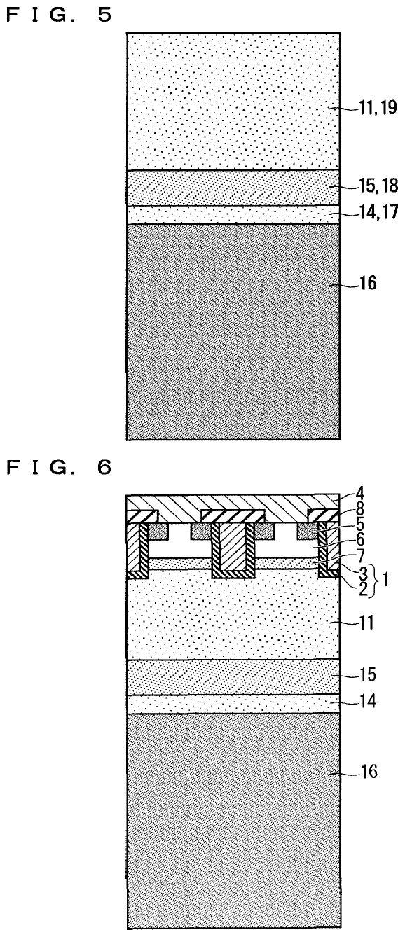

To address this, a manufacturing method according to a second embodiment of the present invention can solve the problem that has occurred in manufacturing the semiconductor device 100 according to the first embodiment. FIGS. 5 to 9 are cross-sectional views of the semiconductor device in each step for illustrating the manufacturing method according to the second embodiment.

First, an n⁺ type silicon substrate 16 that is an n⁺ type semiconductor substrate shown in FIG. 5 is prepared. Note that part of the n⁺ type silicon substrate 16 becomes the n⁺ type first buffer layer 13 in FIG. 2 after the steps described below are performed.

Next, as shown in FIG. 5, an n⁻ type first epitaxial growth layer 17, an n type second epitaxial growth layer 18, and an n⁻ type third epitaxial growth layer 19 are sequentially formed on the upper surface of the n⁺ type silicon substrate 16. The manufacturing method of the n⁺ type silicon substrate 16, serving as a base material for epitaxial growth, is not limited, and the FZ method, the MCZ method, the CZ (Czochralski) method, or the like can be used, for example. The concentration of the substrate and of the epitaxial growth layers on the substrate can be controlled by changing the doping concentration of phosphorus or arsenic, for example. Such a manufacturing method according to the second embodiment can, unlike the proton irradiation with the related semiconductor device, cause the impurity concentration profile to follow the step-like profile described in the first embodiment.

The following describes the difference between a conventional deep buffer layer structure formed by proton irradiation and a buffer layer structure according to the second embodiment formed by epitaxial growth and a method for determining the difference.

In general, it is known that a hydrogen donor is formed when heat treatment is performed after monocrystalline silicon is irradiated with protons. It is considered that a hydrogen donor is formed by an irradiation defect binding with a hydrogen atom accompanying the heat treatment. Irradiation defects reduce the carrier lifetime of the semiconductor device, increase the on-state resistance, and increase the leak current, and therefore, it is preferable that the crystal defects be as small as possible. For this reason, heat treatment at high temperature is required.

However, in general, proton irradiation is performed after the structure on the front side (upper side in FIG. 2) of the semiconductor device is fabricated. In order to prevent damage to the front surface structure of the semiconductor device, the temperature of heat treatment after proton irradiation is limited up to 400° C., for example. For this reason, crystal defects are not sufficiently recovered, and vacancies (V), VO complex defects caused by oxygen (O) atoms, or VOH complex defects with hydrogen (H) added remain in the buffer layer region. On the other hand, since the epitaxial growth method is used in the manufacturing method according to the second embodiment, the deep buffer layer is formed in the wafer state and in a state in which defects that reduce the lifetime are suppressed before the front surface structure is formed.

Also, in general, after the surface of the semiconductor device is formed, the semiconductor device is ground from the back surface side to be thinned before proton irradiation. This reduction in thickness leads to variations in the thickness of approximately 1 μm to 5 μm. For this reason, when proton irradiation is performed under the same conditions, an error of the same degree as the thickness variations occurs in the back surface carrier profile. The irradiation depth of protons to the wafer can be controlled by an absorber made of aluminum foil or the like. However, it is difficult to adjust the back surface carrier profile using the absorber because exchanging the absorber according to the wafer's grinding errors extremely reduces the production efficiency, and the grinding thickness errors cannot be reduced in the proton irradiation process. As a result of the above, when it is intended to form a low impurity concentration layer on the back surface by proton irradiation, its depth seen from the front surface will vary among the semiconductor devices. On the other hand, in the second embodiment, the n⁻ type back surface carrier accumulation layer 14, the n⁺ type first buffer layer 13, and the n type second buffer layer 15 are formed in advance by epitaxial growth, and therefore, the depth of the impurity concentration layer viewed from the surface side of the n⁻ type back surface carrier accumulation layer 14 can be constant. For this reason, the variations in manufacture can be suppressed.

Several methods can be considered to determine whether the deep buffer layer is formed by proton irradiation or by epitaxial growth. For example, a Deep Level Transient Spectroscopy (DLTS) method can be used to determine the manufacturing method depending on whether or not peaks derived from VO complex defects or VOH complex defects are detected. As another method, the manufacturing method can be determined based on whether or not hydrogen atoms having different concentrations remain at the peak position of the n type impurity concentration of each buffer layer. For example, in FIGS. 2 and 3, the hydrogen atom concentration in each of the n⁻ type drift layer 11 and the n type second buffer layer 15 is measured, for example, by Secondary Ion Mass Spectrometry (SIMS) method. Then, if the two layers measured have an equal concentration, it can be determined that the buffer layer is formed by epitaxial growth, and if these layers measured have different concentrations, it can be determined that the buffer layer is formed by proton irradiation.

As the magnitude relationship between the n type impurity concentrations of the layers, the impurity concentration of the n⁻ type first epitaxial growth layer 17 is the lowest, and the impurity concentration of the n type second epitaxial growth layer 18 is higher than the impurity concentration of the n⁻ type third epitaxial growth layer 19. Through the above steps, the n⁻ type back surface carrier accumulation layer 14, the n type second buffer layer 15, and the n⁻ type drift layer 11 are sequentially formed on the upper surface of the n⁺ type silicon substrate 16 by epitaxial growth.

Subsequently, as shown in FIG. 6, the trench gate electrode 1, the emitter electrode 4, the n⁺ type emitter layer 5, the p type base layer 6, the n type carrier accumulation layer 7, and the interlayer insulating film 8 are formed on or above the upper surface of the n⁻ type drift layer 11.

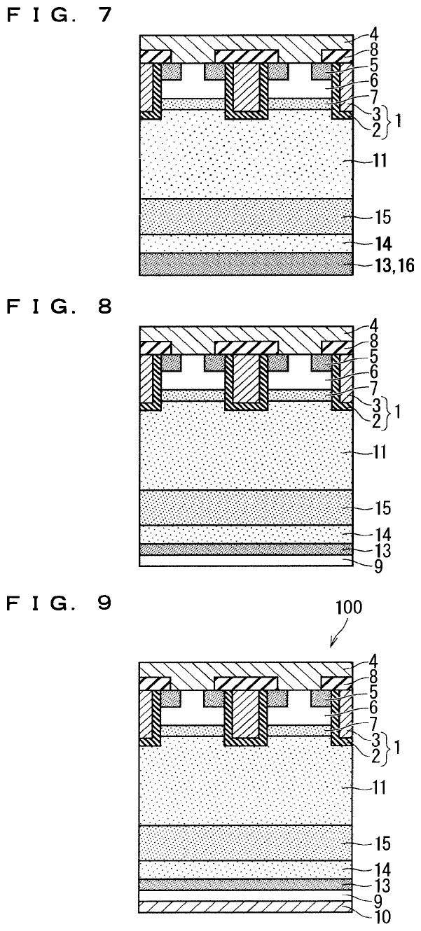

Thereafter, as shown in FIG. 7, the n⁺ type silicon substrate 16 is ground from its back surface side to make the n⁺ type silicon substrate 16 have a predetermined thickness. After grinding, in order to further increase the concentration in the n⁺ type silicon substrate 16, for example, phosphorus or the like may be ion-implanted and then activation may be performed by laser annealing or the like. The n⁺ type first buffer layer 13 is thereby formed.

Furthermore, as shown in FIG. 8, the p⁺ type collector layer 9 is formed by, for example, performing ion implantation of boron and activation annealing such as laser annealing on the lower surface (back surface) of the n⁺ type first buffer layer 13.

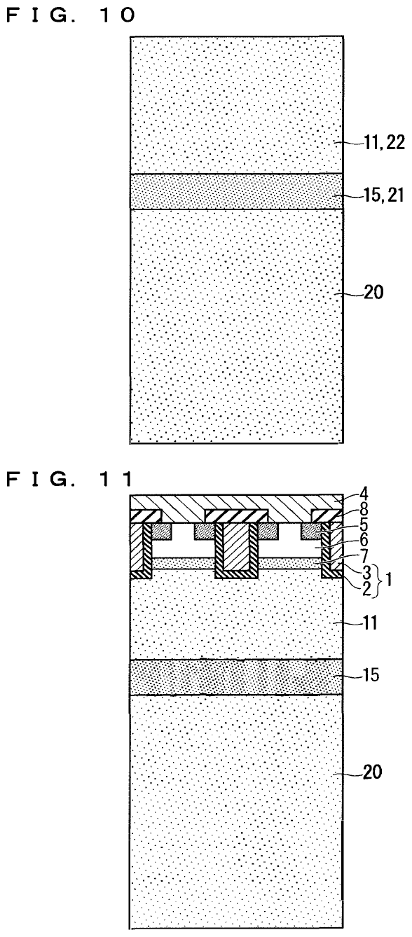

Finally, as shown in FIG. 9, the collector electrode 10 is formed on the lower surface of the p⁺ type collector layer 9. Thus, the semiconductor device 100 according to the first embodiment is completed.

Here, when the n⁺ type silicon substrate 16 is completely ground, the strength of the wafer on which a semiconductor device such as an IGBT is formed is reduced, and there is a concern that the wafer may be broken during manufacture. Therefore, it is preferable to design the thickness of the chip of the semiconductor device such that 2 μm or more of the n⁺ type silicon substrate 16 remains with respect to the upper limit value of grinding error. With such a process, cracking of the wafer can be reduced. In addition, since the n⁺ type silicon substrate 16 can be used as the n⁺ type first buffer layer 13, the number of manufacturing steps can be reduced.

Moreover, proton irradiation may be employed to form a deep buffer layer structure after the manufacturing process of the surface, but proton irradiation fails to make the n type impurity concentration of the buffer layer below the concentration of the substrate. Therefore, even if it is attempted to form a low concentration layer, such as the n⁻ type back surface carrier accumulation layer 14, in the vicinity of the n⁺ type first buffer layer 13 on the back surface by proton irradiation, the concentration cannot be reduced sufficiently. On the other hand, according to the second embodiment, since the concentration of each buffer layer on the back surface can be freely controlled during epitaxial growth, for example, the impurity concentration of the n⁻ type back surface carrier accumulation layer 14 can be designed to be lower than that of the n⁻ type drift layer 11. As described above, the manufacturing method of the second embodiment also has the effect of enhancing the degree of freedom for design of the impurity concentration profile on the back surface.

Furthermore, in the manufacturing method of the second embodiment, since the n⁻ type back surface carrier accumulation layer 14, the n⁺ type first buffer layer 13, and the n type second buffer layer 15 are formed by epitaxial growth, the impurity concentration of each film such as the n⁻ type back surface carrier accumulation layer 14 can be made constant in each film, and the design of the impurity concentrations becomes easy. In addition, since it is easy to form the n⁻ type back surface carrier accumulation layer 14 relatively thickly, for example, 20 μm, the manufacturing method of the second embodiment is advantageous in increasing the amount of accumulated holes and controlling the amount of accumulation.

### Gist of Second Embodiment

With the manufacturing method of the second embodiment, a semiconductor device is manufactured using a silicon substrate on which a desired impurity concentration profile is formed by epitaxial growth in advance. This can facilitate the fabrication of a layered structure composed of a large number of layers including the n⁻ type back surface carrier accumulation layer 14 without introducing special equipment or special processes. Furthermore, by using the epitaxial growth method, it is possible to realize an intended concentration difference between the semiconductor layers (for example, realizing a step-like profile) and an intended thickness of each layer. In addition, by using the remaining portion after grinding of the n⁺ type silicon substrate 16 as the n⁺ type first buffer layer 13, the number of stages of epitaxial layers, the number of ion implantation steps, and the number of laser annealing steps can be reduced, and the strength of the substrate can be increased. This can improve the productivity and yield of semiconductor devices such as IGBTs.

In addition, the n type second buffer layer 15 provided on the n⁻ type back surface carrier accumulation layer 14 acts as a deep buffer layer structure that suppresses the extension of the depletion layer, so that the surge voltage can be further reduced. As described above, by providing the n⁻ type back surface carrier accumulation layer 14 and the n type second buffer layer 15, the surge voltage suppressing effect can be enhanced without increasing the thickness of the chip. As a result, it is possible to provide a power module capable of suppressing defects that have occurred when an overvoltage is applied to semiconductor devices such as IGBTs and also capable of reducing noise.

### Third Embodiment

A manufacturing method according to a third embodiment of the present invention can solve the problem that has occurred in manufacturing the semiconductor device 100 according to the first embodiment, like the manufacturing method according to the second embodiment. FIGS. 10 to 14 are cross-sectional views of the semiconductor device in each step for illustrating the manufacturing method according to the third embodiment.

First, an n⁻ type silicon substrate 20 that is an n⁻ type semiconductor substrate shown in FIG. 10 is prepared. Note that part of the n⁻ type silicon substrate 20 becomes the n⁻ type back surface carrier accumulation layer 14 in FIG. 2 after the steps described below are performed.

Next, as shown in FIG. 10, an n type first epitaxial growth layer 21 and an n⁻ type second epitaxial growth layer 22 are sequentially formed on the upper surface of the n⁻ type silicon substrate 20. Such a manufacturing method according to the third embodiment can cause the impurity concentration profile to follow the step-like profile described in the first embodiment. Through the above steps, the n type second buffer layer 15 and the n⁻ type drift layer 11 are sequentially formed on the upper surface of the n⁻ type silicon substrate 20 by epitaxial growth.

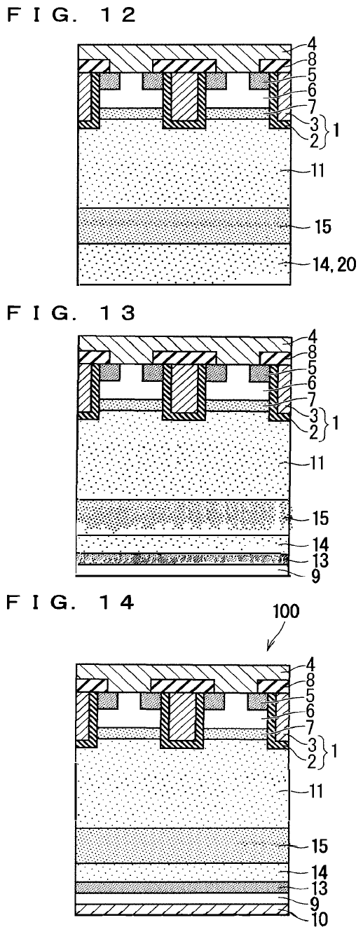

Subsequently, as shown in FIG. 11, the trench gate electrode 1, the emitter electrode 4, the n⁺ type emitter layer 5, the p type base layer 6, the n type carrier accumulation layer 7, and the interlayer insulating film 8 are formed on or above the upper surface of the n⁻ type drift layer 11.

Thereafter, as shown in FIG. 12, the n⁻ type silicon substrate 20 is ground from the back surface side. The n⁻ type back surface carrier accumulation layer 14 is thereby formed. The thickness of the n⁻ type silicon substrate 20 after grinding is preferably 3 μm or more.

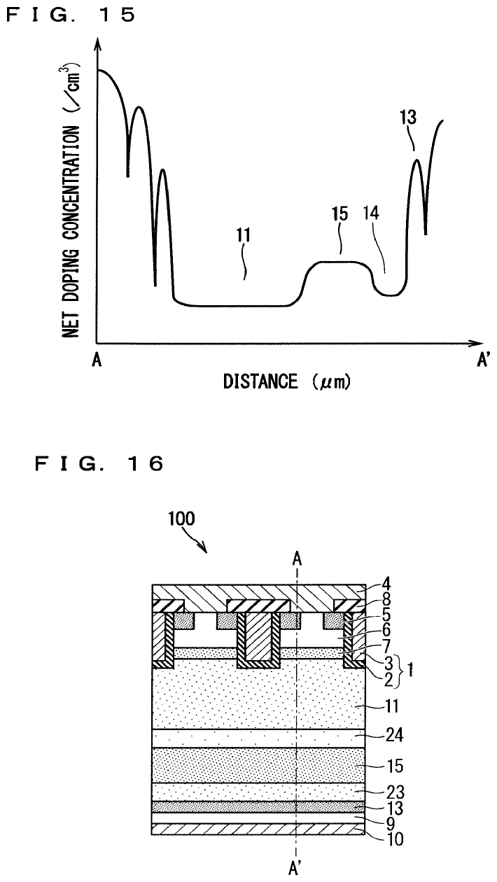

Then, as shown in FIG. 13, the n⁺ type first buffer layer 13 is formed by, for example, performing ion implantation of phosphorus and activation annealing such as laser annealing on the lower surface (back surface) of the n⁻ type silicon substrate 20, that is, on the lower surface of the n⁻ type back surface carrier accumulation layer 14. Furthermore, the p⁺ type collector layer 9 is formed by, for example, performing ion implantation of boron and activation annealing such as laser annealing on the lower surface of the n⁺ type first buffer layer 13.

Finally, as shown in FIG. 14, the collector electrode 10 is formed on the lower surface of the p⁺ type collector layer 9. Thus, the semiconductor device according to the first embodiment is completed. The n type impurity concentration of the n⁻ type back surface carrier accumulation layer 14 of the semiconductor device completed in this manner is lower than the n type impurity concentration of the n⁺ type first buffer layer 13 and the impurity concentration of the n type second buffer layer 15.

### Gist of Third Embodiment

As in the second embodiment described above, in the method of using the remaining portion after grinding of the n⁺ type silicon substrate 16 as the n⁺ type first buffer layer 13, the amount of impurities in the n⁺ type first buffer layer 13 fluctuates greatly due to grinding errors. As a result, the characteristics of semiconductor devices, such as IGBTs, vary from wafer to wafer. On the other hand, with the manufacturing method of the third embodiment, since the n⁻ type silicon substrate 20 is used, the influence of the variations of the amount of impurities in the n⁺ type first buffer layer 13 with respect to variations of the grinding thickness can be reduced. Furthermore, by using the remaining portion after grinding of the n⁻ type silicon substrate 20 as the n⁻ type back surface carrier accumulation layer 14, the number of stages of epitaxial layers can be reduced, and the strength of the substrate can be increased. This can improve the productivity and yield of semiconductor devices such as IGBTs.

### Fourth Embodiment

A semiconductor device 100 according to a fourth embodiment of the present invention has the same cross-sectional configuration as that (FIG. 2) of the semiconductor device 100 according to the first embodiment except for the impurity concentration profile. Hereinafter, among the components described in the fourth embodiment, the same or similar components as or to the components described above are designated by the same reference numerals, and different components will be mainly described.

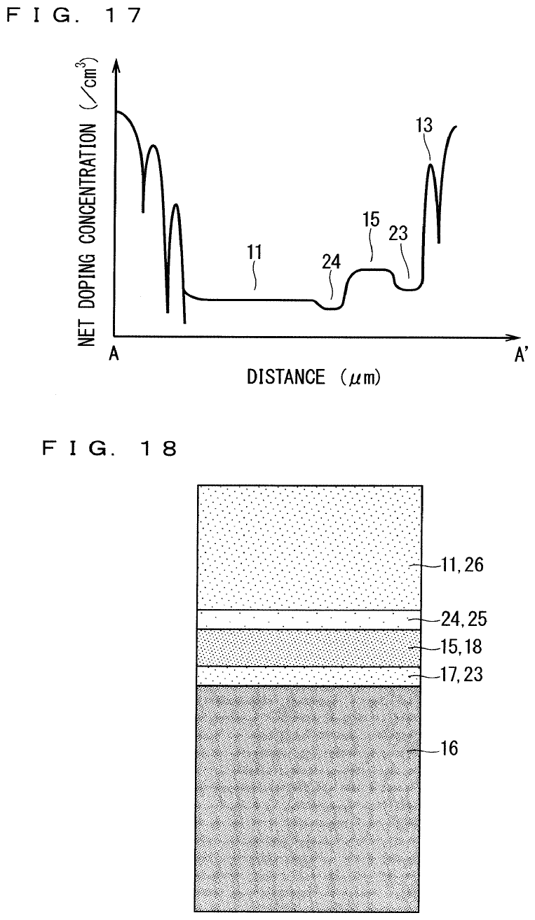

FIG. 15 is a diagram showing an impurity concentration profile along line A-A′ in FIG. 2, that is, a profile of net doping concentration.

In the first embodiment in FIG. 3 described above, the n⁻ type back surface carrier accumulation layer 14 has the lowest n type impurity concentration among the four semiconductor layers described above. By contrast, in the fourth embodiment in FIG. 15, the n⁻ type drift layer 11 has the lowest n type impurity concentration among the four semiconductor layers described above. The n type impurity concentration of the n⁻ type back surface carrier accumulation layer 14 is lower than the n type impurity concentration of the n⁺ type first buffer layer 13 and the n type impurity concentration of the n type second buffer layer 15.

### Gist of Fourth Embodiment

With the configuration as described above, the impurity concentration of the n⁻ type drift layer 11 can be made lower than that of the n⁻ type back surface carrier accumulation layer 14. As a result, the function of the deep buffer layer to moderate the extension of the depletion layer extending to the n⁻ type back surface carrier accumulation layer 14 at turn-off, that is, the function to moderate the extension of the depletion layer can be enhanced. The surge voltage can be thereby suppressed.

### Fifth Embodiment

FIG. 16 is a schematic cross-sectional view showing the configuration of a semiconductor device 100 according to a fifth embodiment of the present invention. Hereinafter, among the components described in the fifth embodiment, the same or similar components as or to the components described above are designated by the same reference numerals, and different components will be mainly described.

The semiconductor device 100 according to the first embodiment includes the n⁺ type first buffer layer 13, the n⁻ type back surface carrier accumulation layer 14, the n type second buffer layer 15, and the n⁻ type drift layer 11. The semiconductor device 100 according to the fifth embodiment includes, instead of these, an n⁻ type first back surface carrier accumulation layer 23 as a first semiconductor layer, the n type second buffer layer 15 as a second semiconductor layer, an n⁻⁻ type second back surface carrier accumulation layer 24 as a third semiconductor layer, an n⁻ type drift layer 11 as a fourth semiconductor layer, and the n⁺ type first buffer layer 13 as a fifth semiconductor layer.

The n⁻ type first back surface carrier accumulation layer 23, the n⁻ type second buffer layer 15, the n⁻⁻ type second back surface carrier accumulation layer 24, and the n⁻ type drift layer 11 are stacked from the bottom to the top. The n⁺ type first buffer layer 13 is disposed between the n⁻ type first back surface carrier accumulation layer 23 and the p⁺ type collector layer 9. In the following description, the n⁻ type first back surface carrier accumulation layer 23, the n type second buffer layer 15, the n⁻⁻ type second back surface carrier accumulation layer 24, the n⁻ type drift layer 11, and the n⁺ type first buffer layer 13 may be collectively referred to as “five semiconductor layers”.

FIG. 17 is a diagram showing an impurity concentration profile along line A-A′ in FIG. 16, that is, a profile of net doping concentration.

The n type impurity concentration of one semiconductor layer which is one of the n type second buffer layer 15 and the n⁻⁻ type second back surface carrier accumulation layer 24 is lower than the n type impurity concentration of each of the semiconductor layer adjacent in the upward direction to the one semiconductor layer and the semiconductor layer adjacent in the downward direction to the one semiconductor layer. In the fifth embodiment, the one semiconductor layer is the n⁻⁻ type second back surface carrier accumulation layer 24, and the n type impurity concentration of the n⁻⁻ type second back surface carrier accumulation layer 24 is lower than the n type impurity concentration of each of the n⁻ type drift layer 11 adjacent in the upward direction and the n type second buffer layer 15 adjacent in the downward direction.

The n⁻⁻ type second back surface carrier accumulation layer 24 has the lowest n type impurity concentration among the five semiconductor layers described above. The n type impurity concentration of the n⁻⁻ type first back surface carrier accumulation layer 23 is lower than the n type impurity concentration of the n type second buffer layer 15 and the n type impurity concentration of the n⁺ type first buffer layer 13. In the fifth embodiment, the profile of the net doping concentration of the five semiconductor layers is a step-like profile.

In addition, the hydrogen atom concentration in the n⁻⁻ type second back surface carrier accumulation layer 24 is the same as the hydrogen atom concentration in n in each of the n⁻ type drift layer 11 adjacent in the upward direction and the n type second buffer layer 15 adjacent in the downward direction. Here, the standard deviation of the hydrogen concentration in the chip depth direction of a total of the five semiconductor layers and the standard deviation of the hydrogen concentration in the chip depth direction of each of the five semiconductor layers are not more than three times the standard deviation of the hydrogen ion concentration in the chip depth direction of the n⁻ type drift layer 11.

<Manufacturing Method>

FIG. 18 is a cross-sectional view of the semiconductor device in the first step for illustrating the manufacturing method according to the fifth embodiment.

First, the n⁺ type silicon substrate 16 that is an n⁺ type semiconductor substrate shown in FIG. 18 is prepared. Note that part of the n⁺ type silicon substrate 16 finally serves as the n⁺ type first buffer layer 13 in FIG. 16.

Next, as shown in FIG. 18, the n⁻ type first epitaxial growth layer 17, the n type second epitaxial growth layer 18, an n⁻⁻ type third epitaxial growth layer 25, and a n⁻ type fourth epitaxial growth layer 26 are sequentially formed on the upper surface of the n⁺ type silicon substrate 16. In other words, on the upper surface of the n⁺ type silicon substrate 16, the n⁻ type first back surface carrier accumulation layer 23, the n type second buffer layer 15, the n⁻⁻ type second back surface carrier accumulation layer 24, and the n⁻ type drift layer 11 are stacked sequentially. Then, in the structure of FIG. 18, steps similar to those in FIGS. 6 to 9 described in the second embodiment are performed. As a result, the semiconductor device 100 according to the fifth embodiment including the n⁻ type first back surface carrier accumulation layer 23 and the n⁻⁻ type second back surface carrier accumulation layer 24, that is, the two-stage back surface carrier accumulation layers, is completed.

### Gist of Fifth Embodiment

With the semiconductor device 100 according to the fifth embodiment including a plurality of back surface carrier accumulation layers, holes can be efficiently accumulated in the conductive state. This can further enhance the depletion of carriers at turn-off, and can further suppress the surge voltage at turn-off.

While the semiconductor device including the two-stage back surface carrier accumulation layers has been described in the fifth embodiment, the same effect as that described above can be achieved by a semiconductor device including three- or more-stage back surface carrier accumulation layers.

### Modification of Fifth Embodiment

The manufacturing method described in the fifth embodiment is similar to the manufacturing method according to the second embodiment, but is not limited thereto, and may be similar to the manufacturing method according to the third embodiment, for example.

FIG. 19 is a cross-sectional view of the semiconductor device in the first step for illustrating the manufacturing method according to the fifth embodiment.

First, the n⁻ type silicon substrate 20 that is an n⁻ type semiconductor substrate shown in FIG. 19 is prepared. Note that part of the n⁻ type silicon substrate 20 finally serves as the n⁻ type first back surface carrier accumulation layer 23 in FIG. 16.

Next, as shown in FIG. 19, the n type first epitaxial growth layer 21, an n⁻⁻ type second epitaxial growth layer 27, and an n⁻ type third epitaxial growth layer 28 are sequentially formed on the upper surface of the n⁻ type silicon substrate 20. In other words, on the upper surface of the n⁻ type silicon substrate 20, the n type second buffer layer 15, the n⁻⁻ type second back surface carrier accumulation layer 24, and the n⁻ type drift layer 11 are stacked sequentially. Then, in the structure of FIG. 19, steps similar to those in FIGS. 10 to 14 described in the third embodiment are performed. As a result, the semiconductor device 100 according to the fifth embodiment including the n⁻ type first back surface carrier accumulation layer 23 and the n−− type second back surface carrier accumulation layer 24, that is, the two-stage back surface carrier accumulation layers, is completed.

According to this modification as described above, the number of one-stage epitaxial layers can be reduced as compared with the manufacturing method described in the fifth embodiment, and therefore the productivity of the semiconductor device is improved. As in the fifth embodiment, the same effect as that described above can be achieved by manufacturing a semiconductor device including three- or more-stage back surface carrier accumulation layers in the present modification.

### Sixth Embodiment

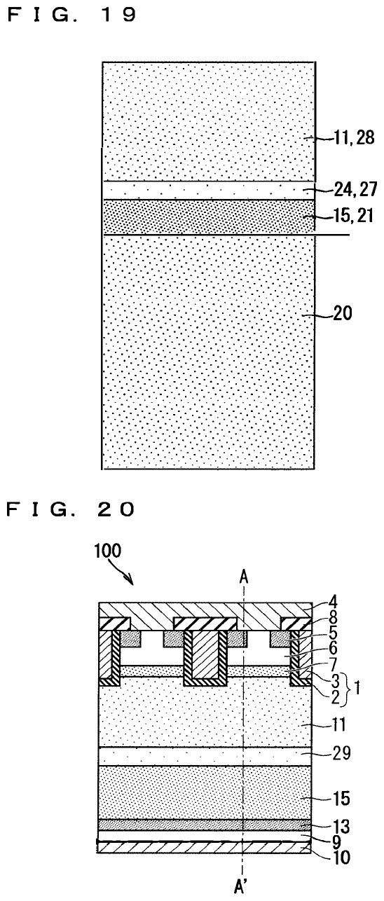

FIG. 20 is a schematic cross-sectional view showing the configuration of a semiconductor device 100 according to a sixth embodiment of the present invention. Hereinafter, among the components described in the sixth embodiment, the same or similar components as or to the components described above are designated by the same reference numerals, and different components will be mainly described.

The semiconductor device 100 according to the sixth embodiment is the same as the configuration of the fifth embodiment except the n⁻ type first back surface carrier accumulation layer 23. The semiconductor device 100 according to the sixth embodiment includes the n⁺ type first buffer layer 13 as a first semiconductor layer, the n type second buffer layer 15 as a second semiconductor layer, an n⁻⁻ type back surface carrier accumulation layer 29 as a third semiconductor layer, and the n⁻ type drift layer 11 as a fourth semiconductor layer. In the following description, the n⁺ type first buffer layer 13, the n type second buffer layer 15, the n⁻⁻ type back surface carrier accumulation layer 29, and the n⁻ type drift layer 11 may be collectively referred to as “four semiconductor layers”.

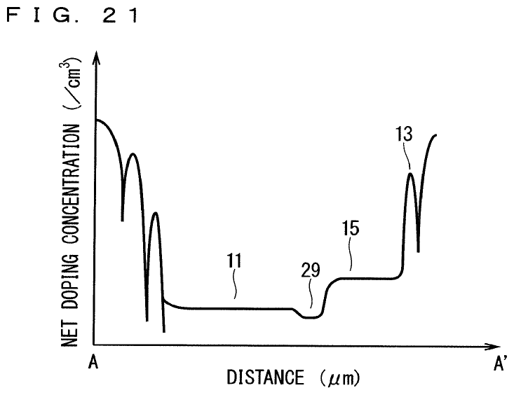

FIG. 21 is a diagram showing an impurity concentration profile along line A-A′ in FIG. 21, that is, a profile of net doping concentration.

The n type impurity concentration of one semiconductor layer which is one of the n type second buffer layer 15 and the n⁻⁻ type back surface carrier accumulation layer 29 is lower than the n type impurity concentration of each of the semiconductor layer adjacent in the upward direction to the one semiconductor layer and the semiconductor layer adjacent in the downward direction to the one semiconductor layer. In the sixth embodiment, the one semiconductor layer is the n⁻⁻ type back surface carrier accumulation layer 29, and the n type impurity concentration of the n⁻⁻ type back surface carrier accumulation layer 29 is lower than the n type impurity concentration of each of the n⁻ type drift layer 11 adjacent in the upward direction and the n type second buffer layer 15 adjacent in the downward direction.

The n⁻⁻ type back surface carrier accumulation layer 29 has the lowest n type impurity concentration among the four semiconductor layers described above. The n type impurity concentration of the n⁺ type first buffer layer 13 is higher than the n type impurity concentration of the n type second buffer layer 15. In the sixth embodiment, the profile of the net doping concentration of the four semiconductor layers is a step-like profile.

In addition, the hydrogen atom concentration in the n⁻⁻ type back surface carrier accumulation layer 29 is the same as the hydrogen atom concentration in n in each of the n⁻ type drift layer 11 adjacent in the upward direction and the n type second buffer layer 15 adjacent in the downward direction. Here, the standard deviation of the hydrogen concentration in the chip depth direction of a total of the four semiconductor layers and the standard deviation of the hydrogen concentration in the chip depth direction of each of the four semiconductor layers are not more than three times the standard deviation of the hydrogen ion concentration in the chip depth direction of the n⁻ type drift layer 11.

### Gist of Sixth Embodiment

The impurity concentrations of the upper and lower semiconductor layers (the n type second buffer layer 15 and the n⁻ type drift layer 11) in contact with the n⁻⁻ type back surface carrier accumulation layer 29 according to the sixth embodiment are lower than the impurity concentrations of the upper and lower semiconductor layers (the n⁺ type first buffer layer 13 and the n type second buffer layer 15) in contact with the n⁻ type back surface carrier accumulation layer 14 (FIG. 2) according to the first embodiment. Therefore, according to the sixth embodiment, in the heating step in the manufacturing process of the semiconductor device, an increase in the impurity concentration of n⁻ type back surface carrier accumulation layer 29 can be suppressed as a result of the diffusion of impurities from the upper and lower layers. This can suppress loss of the carrier accumulation effect of the carrier accumulation layer.

### Modifications of First to Sixth Embodiments

In the first to sixth embodiments described above, the material of each of the four semiconductor layers or the material of each of the five semiconductor layers is described as silicon. However, the material of these semiconductor layers is not limited to silicon, and may be, for example, a wide band gap semiconductor such as gallium nitride, silicon carbide, aluminum nitride, diamond, or gallium oxide. Furthermore, while the semiconductor device 100 has been described by taking the trench gate type IGBT as an example, the same effect can be obtained even with a planar gate type IGBT. The present invention can also be applied to reverse conducting IGBT (RC-IGBT) and the like.

In the present invention, within the scope of the present invention, the embodiments and modifications can be freely combined, or the embodiments and modifications can be suitably modified and omitted.

Although the present invention has been described in detail, the above description is an exemplification in all aspects, and the present invention is not limited thereto. It is understood that countless modifications not illustrated are conceivable without departing from the scope of the present invention.

### EXPLANATION OF REFERENCE SIGNS

3: Gate electrode
5: n⁺ type emitter layer
6: p⁺ type base layer
9: p⁺ type collector layer
10: Collector electrode
11: n⁻ type drift layer
13: n⁺ type first buffer layer
14: n⁻ type back surface carrier accumulation layer
15: n type second buffer layer
16: n⁺ type silicon substrate
20: n⁻ type silicon substrate
23: n⁻ type first back surface carrier accumulation layer
24: n⁻⁻ type second back surface carrier accumulation layer
29: n⁻⁻ type back surface carrier accumulation layer.

1: A semiconductor device comprising:
a first semiconductor layer, a second semiconductor layer, a third semiconductor layer, and a fourth semiconductor layer, each having a first conductivity type, the first to fourth semiconductor layers being stacked in this order, a forward direction and a reverse direction of the stacking being respectively referred to as a first direction and a second direction;
a base layer disposed on a surface side of the fourth semiconductor layer facing the first direction, the base layer having a second conductivity type;
an emitter layer selectively disposed on a surface of the base layer facing the first direction, the emitter layer having the first conductivity type;
a gate electrode capable of forming a channel in the base layer;
a collector layer disposed on a side of the second direction of the first semiconductor layer, the collector layer having the second conductivity type; and
a collector electrode disposed on a surface of the collector layer facing the second direction; wherein
an impurity concentration of the first conductivity type of the third semiconductor layer is lower than an impurity concentration of the first conductivity type of each of the fourth semiconductor layer adjacent in the first direction to the third semiconductor layer and the second semiconductor layer adjacent in the second direction to the third semiconductor layer,
the third semiconductor layer has a lowest impurity concentration of the first conductivity type among the first to fourth semiconductor layers,
an impurity concentration of the first conductivity type of the first semiconductor layer is higher than an impurity concentration of the first conductivity type of the second semiconductor layer, and
a hydrogen atom concentration in the third semiconductor layer is same as a hydrogen atom concentration in each of the fourth semiconductor layer adjacent in the first direction to the third semiconductor layer and the second semiconductor layer adjacent in the second direction to the third semiconductor layer.

2-6. (canceled)

7: The semiconductor device according to claim 1, further comprising
a fifth semiconductor layer of the first conductivity type disposed between the first semiconductor layer and the collector layer, wherein
the third semiconductor layer has a lowest impurity concentration of the first conductivity type among the first to fifth semiconductor layers, and
an impurity concentration of the first conductivity type of the first semiconductor layer is lower than an impurity concentration of the first conductivity type of the second semiconductor layer and an impurity concentration of the first conductivity type of the fifth semiconductor layer.

8. (canceled)

9: The semiconductor device according to claim 1, wherein
a maximum value of an impurity concentration of the second conductivity type of the collector layer is 10 or more times a maximum value of an impurity concentration of the first conductivity type of the first semiconductor layer.

10. (canceled)
